(19) United States
(12) Patent Application Publication
(10) Pub. No.: US 2025/0169042 A1
(43) Pub. Date: May 22, 2025

(54) THERMAL MANAGEMENT ARRANGEMENT FOR AN ELECTRONIC CONTROL UNIT

(71) Applicant: ZF Friedrichshafen AG, Frieddrichshafen (DE)

(72) Inventors: Chirag Hiremath, Canton, MI (US); Thomas E. Blake, III, Novi, MI (US)

(21) Appl. No.: 18/952,410

(22) Filed: Nov. 19, 2024

Related U.S. Application Data
(60) Provisional application No. 63/600,754, filed on Nov. 20, 2023.

(51) Int. Cl. H05K 7/20

(52) U.S. Cl. CPC H05K 7/2039

(57) ABSTRACT

An electronic control unit is disclosed which comprises an outer housing, a printed circuit board, at least one electrical component connected to the printed circuit board, a heat spreader layer disposed between the electrical component and the outer housing and including at least a portion in contact with the outer housing, and a thermal interface material disposed between the heat spreader layer and the outer housing.

### CROSS-REFERENCE TO RELATED APPLICATIONS

This application claims priority to U.S. provisional application No. 63/600,754, filed on Nov. 20, 2023, the disclosure of which is incorporated herein by reference in its entirety.

### TECHNICAL FIELD

The present disclosure relates generally to electronic control unit for a vehicle system and in one exemplary arrangement, for an electronic control unit and onboard vehicle camera system.

### BACKGROUND

Electronic components, such as vehicle onboard computing systems may include heat generating components, i.e., integrated circuits, displays, and the like. The performance of such electronic devices may be limited and/or diminished by heat dissipation capabilities of the electronic devices. Accordingly, to maximize the performance capabilities of such electronic devices, various strategies have been employed to dissipate heat generated by such components.

For example, in one exemplary arrangement, electronic components are individually thermally coupled to a metal enclosure with thermal interface material, such as thermal pads, thermal gels, thermal pastes, etc. While these materials provide a passive option for heat to disperse to the metal enclosure, the heat distribution may not be uniform, leading to hot spots and potential performance degradation. Alternative cooling strategies for electronic control units with high power may include active cooling solutions, such as fans for cooling channels. However, such arrangements are expensive, increase cost and require increased packaging space.

Moreover, electronic control unit enclosures are typically die cast with inexpensive materials such as aluminum. Although the thermal conductivity of aluminum is good, it is only about one third as conductive as copper. However, utilizing copper as the electronic control unit enclosure is not practical due to its high cost. Accordingly, there is a need for a low cost, with small package size and reduced complexity solutions for managing heat dissipation of electronic control units.

### SUMMARY

In one exemplary arrangement, an electronic control unit is disclosed which comprises an outer housing, a printed circuit board, at least one electrical component connected to the printed circuit board, a heat spreader layer disposed between the electrical component and the outer housing and including at least a portion in contact with the outer housing, and a thermal interface material disposed between the heat spreader layer and the outer housing.

In one exemplary arrangement, the heat spreader layer is constructed of copper.

In one exemplary arrangement, there is a plurality of electrical components connected to the printed circuit board of varying sizes.

In one exemplary arrangement, there is a second heat spreader layer provided such that a first heat spreader layer is disposed on one side of the printed circuit board and the second heat spreader layer is provided on an opposite side of the printed circuit board.

In one exemplary arrangement, there are one or more electrical components connected to a bottom surface of the printed circuit board, and the second heat spreader layer is disposed between the electrical components connected to the bottom surface of the printed circuit board and a cover member.

In one exemplary arrangement, a cover member is disposed below the printed circuit board, and thermal interface material is disposed between the printed circuit board and the cover member. In one exemplary arrangement, the cover member that operatively connects to the outer housing to define a space in which the printed circuit board, electrical components and heat spreader layer are disposed.

In one exemplary arrangement, the outer housing is constructed of aluminum.

In one exemplary arrangement, an electronic control unit is disclosed that comprises an outer housing member and a cover member; a printed circuit board; a first heat spreader layer and a second heat spreader layer. A plurality of electrical components are connected to top and bottom surfaces of the printed circuit board, wherein the electrical components are of varying sizes. The first heat spreader layer is disposed between the electrical components disposed on the top surface of the printed circuit board and the outer housing. At least a portion of the first heat spreader layer is in contact with the outer housing. The second heat spreader layer is disposed between the electrical components disposed on the bottom surface of the printed circuit board and the cover member and at least a portion of the second heat spreader layer is in contact with the cover member.

### BRIEF DESCRIPTION OF THE DRAWINGS

The foregoing and other features and advantages of the present disclosure will become apparent to those skilled in the art to which the present disclosure relates upon reading the following description with reference to the accompanying drawings, in which:

FIG. 1 is a perspective view of an exemplary arrangement of an electronic control unit mounted in a vehicle;

FIG. 2 is a partially exploded view of the electronic control unit of FIG. 1;

FIG. 3 is a perspective view of internal components of the electronic control unit of FIG. 1;

FIG. 4 is a further perspective view of additional internal components of the electronic components of the electronic control unit of FIG. 1; and

FIG. 5 is a cross-sectional view of the electronic control unit of FIG. 1.

### DETAILED DESCRIPTION

Referring now to the discussion that follows, and to the drawings, illustrative approaches to the disclosed systems and methods are shown in detail Although the drawings represent some possible approaches, the drawings are not necessarily to scale and certain features may be exaggerated, removed, or partially sectioned to better illustrate and explain the present disclosure. Further, the descriptions set forth herein are not intended to be exhaustive or otherwise limit or restrict the claims to the precise forms and configurations shown in the drawings and disclosed in the following detailed description.

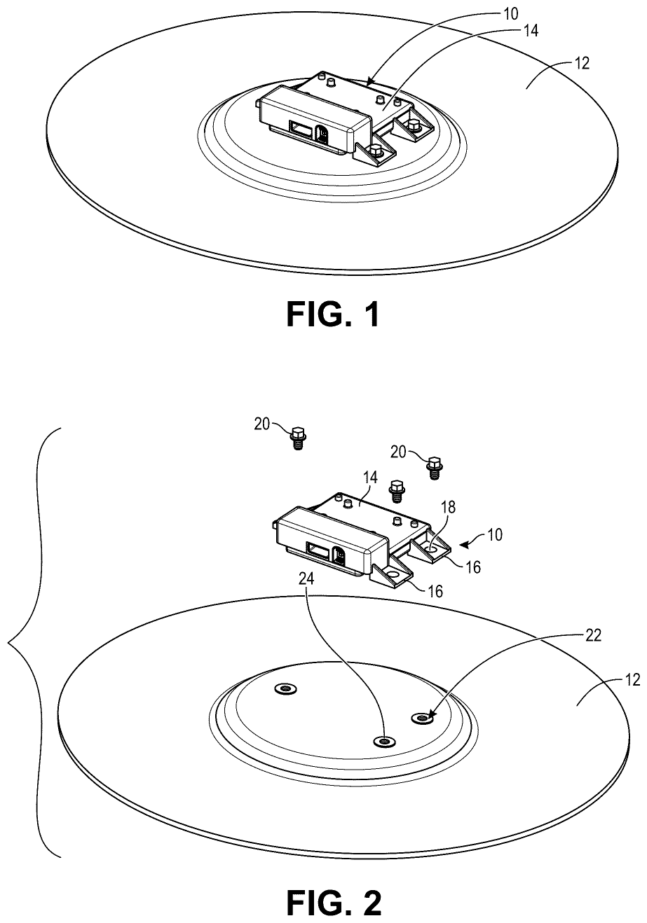

Referring to FIGS. 1-5, and exemplary arrangement of an electronic control unit (“ECU”) 10 is illustrated. In the exemplary arrangement illustrated, the ECU 10 is illustrated as being operatively mounted to a vehicle frame 12, which is schematically represented in FIGS. 1 and 2. The ECU 10 may be secured to the vehicle frame 12 by suitable fasteners. For example, in one exemplary arrangement, the ECU 10 may includes an outer housing 14 that includes at least a pair of mounting tabs 16. Each mounting tab 16 may include a mounting opening 18 that is configured to receive a fastener 20 therethrough. The fasteners 20 are received in corresponding receiving openings 22 disposed in the vehicle frame 12. The receiving openings 22 may include weld nuts 24 to secure the fasteners 20, which may be constructed as bolts, as shown in FIGS. 1-2.

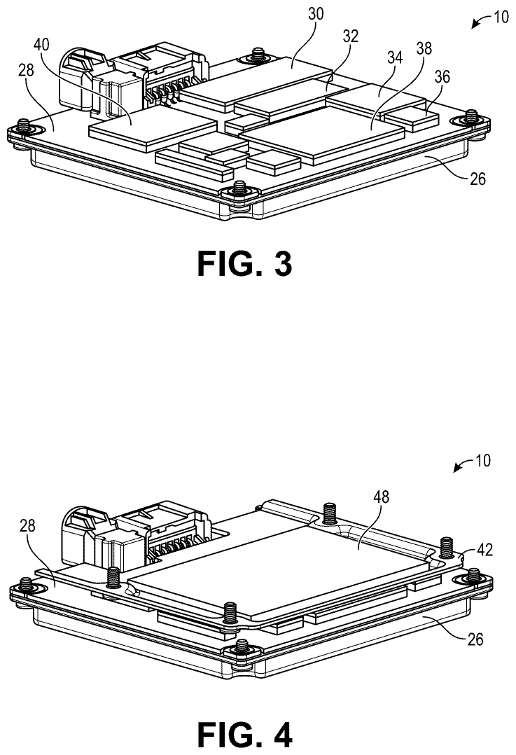

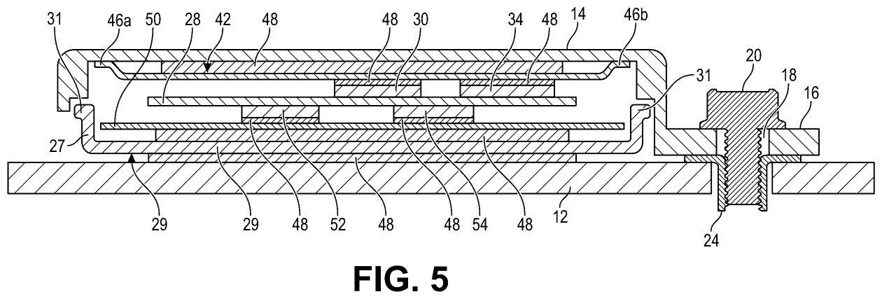

Referring to FIGS. 3-5, details the exemplary ECU 10 are shown. As shown in FIG. 5, for example, the outer housing member 14, which may be constructed of aluminum, may be constructed as a unitary member, with the mounting tabs 16 extending outwardly therefrom. In one exemplary arrangement, the mounting tabs 16 may be integrally formed with the outer housing member 14, as shown in FIG. 5. Spaced from and lying generally parallel to the outer housing member 14 is a cover member 26. The cover member 26 may also be constructed from aluminum.

In one exemplary arrangement, the cover member 26 includes an annular wall 27 that extends upwardly from a base member 29 and around a perimeter of the cover member 26. An upper end of the annular wall 27 may further include a locking member 31 that is configured to engage with a corresponding locking member disposed on housing 14 such that the housing 14 and cover member 26 cooperate to enclose various components of the ECU 10 within a space defined by the housing 14 and cover member 26.

For example, disposed with the outer housing member 14 are various components for the ECU 10, including, but not limited to, a printed circuit board 28. The printed circuit board 28 is disposed within the outer housing member 14 with a number of electrical components 30, 32, 34, 36, 38, 40, integrated thereto. However, as the different electrical components 30, 32, 34, 36, 38 and 40 are different sizes and have different heat generating capacities, simply using thermal interface material alone to direct heat to the outer housing member 14 or the cover member 26 does not adequately dissipate heat uniformly across the ECU 10. Rather, heat tends to dissipate in concentrated locations adjacent the respective electrical components 30, 32, 34, 36, 38, and 40.

To achieve more uniformly in connection with heat dissipation across the entire ECU 10, it is proposed to add a heat spreader layer 42 that extends across the entirety of all of the electrical components 30, 32, 34, 36, 38, and 40 and has at least a portion that is contact with the outer housing. In one exemplary arrangement, fastening elements 41 extend through openings 43 formed through the heat spreader layer 42. The fastening element 41 are configured to engage outer housing 14 in a known manner.

In one exemplary arrangement, the heat spreader layer 42 is constructed of copper. Because it is utilized within the ECU 10, a relatively thin layer may be utilized, such that use of copper is cost effective.

Referring to FIG. 5, in one exemplary arrangement, the heat spreader layer 42 is defined by a main body section 44 with end sections 46a and 46b. The end sections 46a and 46b engage inner surfaces of the outer housing member 14 to facilitate heat transfer to the other housing member 14. Thermal interface material 48, such as thermal pads, thermal gels, thermal pastes, may be disposed between the outer housing material 14 and the heat spreader layer 42. Use of the heat spreader layer 42 allow for a uniform dissipation across the entirety of the EUC 10 to provide for more efficient and reliable, as well as uniform heat dissipation for all of the electrical components 30, 32, 34, 36, 38, 40.

In one exemplary arrangement, a second heat spreader layer 50 is provided, for example, as shown in FIG. 5. The second heat spreader layer 50 is disposed on a side of the printed circuit board 28 opposite where heat spreader layer 42 is disposed and has a portion that is in contact with the cover member 26. Electronic components 52, 54 are disposed on a bottom surface of the printed circuit board 28 with thermal interface material 48 being disposed between the second heat spreader layer 50 and the electronic components 52, 54. Another layer of thermal interface material 48 is disposed between the second heat spreader layer 50 and the cover member 26. A further layer of thermal interface material 48 may be disposed between cover member 26 and the vehicle body 12. And layers of thermal interface material 48 may also be provided between the electrical components and the first and second heat spreader layers, respectively.

What have been described above are examples of the present disclosure. It is, of course, not possible to describe every conceivable combination of components or methodologies for purposes of describing the present invention, but one of ordinary skill in the art will recognize that many further combinations and permutations of the present invention are possible. While certain novel features of this disclosure shown and described below are pointed out in the annexed claims, the disclosure is not intended to be limited to the details specified, since a person of ordinary skill in the relevant art will understand that various omissions, modifications, substitutions and changes in the forms and details of the disclosure illustrated and in its operation may be made without departing in any way from the spirit of the present disclosure. Accordingly, the present disclosure is intended to embrace all such alterations, modifications, and variations that fall within the scope of the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements. No feature of the disclosure is critical or essential unless it is expressly stated as being “critical” or “essential.”

What is claimed is:

1. An electronic control unit, comprising:
an outer housing;
a printed circuit board;
at least one electrical component connected to the printed circuit board,
a heat spreader layer disposed between the electrical component and the outer housing and including at least a portion in contact with the outer housing; and
thermal interface material disposed between the heat spreader layer and the outer housing.

2. The electronic control unit of claim 1, wherein the heat spreader layer is constructed of copper.

3. The electronic control unit of claim 1, wherein there is a plurality of electrical components connected to the printed circuit board of varying sizes.

4. The electronic control unit of claim 1, wherein there is a second heat spreader layer provided such that a first heat spreader layer is disposed on one side of the printed circuit board and the second heat spreader layer is provided on an opposite side of the printed circuit board.

5. The electronic control unit of claim 4, wherein there are one or more electrical components connected to a bottom surface of the printed circuit board, and wherein the second heat spreader layer is disposed between the electrical components connected to the bottom surface of the printed circuit board and a cover member.

6. The electronic control unit of claim 1 further comprising a cover member disposed below the printed circuit board, wherein thermal interface material is disposed between the printed circuit board and a cover member.

7. The electronic control unit of claim 1, wherein the outer housing is constructed of aluminum.

8. The electronic control unit of claim 1, further comprising a cover member that operatively connects to the outer housing to define a space in which the printed circuit board, electrical components and heat spreader layer are disposed.

9. An electronic control unit, comprising:
an outer housing member and a cover member;
a printed circuit board;
a plurality of electrical components connected to a top and bottom surface of the printed circuit board, wherein the electrical components are of varying sizes;
a first heat spreader layer disposed between the electrical components disposed on the top surface of the printed circuit board and the outer housing and including at least a portion in contact with the outer housing; and
a second heat spreader layer disposed between the electrical components disposed on the bottom surface of the printed circuit board and the cover member, wherein a portion of the second heat spreader layer contacts the cover member.

10. The electronic control unit of claim 9, further comprising thermal interface material disposed between the first heat spreader layer and the outer housing.

11. The electronic control unit of claim 9, further comprising thermal interface material disposed between the second heat spreader layer and the cover member.

12. The electronic control unit of claim 9, further comprising thermal interface material disposed on an outside surface of the cover.

13. The electronic control unit of claim 9, further comprising thermal interface material disposed between the electrical components disposed on the top surface of the printed circuit board and the first heat spreader layer.

14. The electronic control unit of claim 9, further comprising thermal interface material disposed between the electrical components disposed on the bottom surface of the printed circuit board and the second heat spreader layer.

15. The electronic control unit of claim 9, wherein the first and second heat spreader layers are constructed of copper.
